(19) United States
(12) Patent Application Publication
(10) Pub. No.: US 2010/0101642 A1
(43) Pub. Date: Apr. 29, 2010

(54) Large-Area Transparent Electroconductive Film and Method of Making the Same

(75) Inventors: Shoji Kaneko, Hamamatsu-shi (JP); Nobuyuki Horikawa, Hamamatsu-shi (JP); Shunji Kawasaki, Hamamatsu-shi (JP)

Correspondence Address: Rahman LLC, 10025 Governor Warfield Parkway, Suite 110, Columbia, MD, 21044, US

(73) Assignee: SPD LABORATORY, INC., Hamamatsu-shi, Shizuoka (JP)

(21) Appl. No.: 12/531,768

(22) PCT Filed: Feb. 25, 2008
(86) PCT No.: PCT/JP2008/053170

§ 371 Date: Sep. 17, 2009

(30) Foreign Application Priority Data
Mar. 23, 2007 (JP) 2007-076943

(51) Int. Cl. B32B 9/00; H01L 31/0216; B05D 5/12

(52) U.S. Cl. 136/256; 428/220; 427/58

(57) ABSTRACT

A large-area transparent electroconductive film having a high visible light transmittance, a suitable haze and a low sheet resistance and having an excellent in uniformity on a film surface and which does not require special crystal orientation. The large-area transparent electroconductive film according to the present invention is characterized in that the film is a fluorine-doped tin oxide film having a film thickness of 0.3 to 1 μm, an average light transmittance is 70 to 90% in a wavelength range of 400 to 800 nm, a haze is 2 to 20% and a sheet resistance is 2 to 15 Ω/□.

### TECHNICAL FIELD

The present invention relates to a transparent electroconductive film and method of making the same. More specifically, the present invention relates to a large-area transparent electroconductive film comprising fluorine-doped tin oxide which can be suitably used in such as solar cells (particularly, dye sensitive solar cells), liquid crystal displays and plasma displays.

### BACKGROUND ART

As transparent electroconductive films have specific properties of being transparent and electrically conductive, such films have been used in transparent electrodes of such as solar cells (particularly, dye sensitive solar cells), liquid crystal displays and plasma displays and in electrodes of display elements of such as laptop computers and cell phones.

As a material for transparent electroconductive films, indium tin oxide (hereinafter, referred to as ITO), fluorine-doped tin oxide (hereinafter, referred to as FTO) or aluminum- or gallium-doped zinc oxide has been used, for example. Among those materials, ITO films have been widely used in transparent electrodes of such as liquid crystal displays, plasma displays, personal computers, games or cell phones since ITO films have low resistivities (1.5×10⁻⁴ to 2.0×10⁻⁴ Ωcm) and are easily etched.

However, there is a disadvantage that a transparent electroconductive film material comprising ITO is expensive due to limited indium resources and is not economical. There is also a disadvantage that the resistivity of a formed electroconductive film increases by heat treatment at approximately 500° C. and thus such material cannot be used in products such as solar cells which require a manufacturing process at a high temperature. On the other hand, FTO does not have a low resistivity (approximately 5.0×10⁻⁴ Ωcm) as compared to ITO. However since FTO has a superior heat resisting property and receives fewer resource effects, it has been recognized as a low-cost electroconductive material which can be alternative to ITO. Aluminum- or gallium-doped zinc oxide is inexpensive. However, there is a disadvantage that it has a high resistivity (approximately 1.0×10⁻³ Ωcm).

As an alternative method, the inventors had proposed a method for making an FTO film at a low temperature by spraying a material solution obtained by adding a fluorine compound to a tetrabutyltin solution or tin tetrachloride solution to which hydrogen peroxide is added as an oxidizer on a substrate with a spray pyrolysis method (see Japanese Unexamined Patent Publication No. 146536/2002). Although the method enables a film to be formed at a low temperature, there is a drawback that the method requires hydrogen peroxide as an oxidizer and its strong oxidizing property may corrode a spraying device. It is also that an FTO film made according to the method is provided with the data as to a light transmittance and electrical resistance of the film. However, there is a drawback that a haze which is important when using films as a transparent electroconductive film in such as solar cells and thus it is not possible to adjust diffusion light for effective use.

As to the basic properties of a transparent electroconductive film, there are visible light transmittance, sheet resistance and haze which show opposing relations to others. When film thickness increases, the sheet resistance decreases, however, the visible light transmittance also decreases and haze increases. A transparent electroconductive film needs to meet all of the three properties. As an FTO transparent electroconductive film used in dye sensitive solar cells, an FTO film which has a low sheet resistance by defining such as film thickness, fluorine concentration, diffraction intensity ratio of X-ray diffraction patterns has been proposed (see Japanese Unexamined Patent Publication No. 3227/2006). However, since a visible light transmittance and haze which are important for a transparent electroconductive film are not defined for such FTO film, there is a drawback that optical property cannot be optimized.

Furthermore, as a transparent electroconductive film, there has been proposed an FTO-ITO laminated film having the advantages of both films which are the low resistance property of an ITO film and heat resistance property of an FTO film (see Japanese Unexamined Patent Publication No. 323818/2003). Although heat resistance property of the film is improved, there is a drawback that the film manufacturing process is complex since the FTO-ITO laminated film is a laminated film.

Recently, transparent electroconductive films used in such as solar cells, liquid crystal displays or plasma displays tend to have a large area. As a result, it is further desirable to provide uniform quality on a film surface. The spray pyrolysis method is an excellent method for readily forming a large-area thin film of such as metal oxide in the atmosphere. However, since conventional film making methods use a fixed spraying nozzle to spray a material solution, there is a problem that film thickness varies between the center portion and edge portions of a substrate and uneven properties appear on a film surface when a substrate has a large area.

In this manner, an ITO film has drawbacks of low heat resistance and high manufacturing costs, a ZnO film has a drawback of high resistance and an FTO-ITO laminated film has a drawback of complex film manufacturing processes. Furthermore, in thin-film formation by means of the spray pyrolysis method, it is required to achieve uniform properties on a film surface. Furthermore, an FTO film is expected to be a high quality film with a suitable haze without the need of a special crystal orientation. Japanese Patent No. 3655330 discloses a film forming method of a tin oxide (IV) film in which a tin oxide (IV) film with a high orientation property can be formed in the early stage of the film formation without the need of providing a buffer layer on a base surface nor the change in film forming condition during film formation. However, since a tin oxide (IV) film has a resistivity of approximately 5.0×10⁻¹ Ωcm and thus has a high sheet resistance, there has been a problem that the film cannot be used as a transparent electroconductive film used in solar cells or displays as it is.

### SUMMARY

The present invention is provided in consideration of the above-mentioned prior art and an object thereof is to make a transparent electroconductive film with high quality. In other words, an object of the present invention is to provide a large-area transparent electroconductive film which has a high visible light transmittance, a suitable haze and a low sheet resistance and which is excellent in uniform properties on a film surface and which does not require a special crystal orientation.

Furthermore, an object of the present invention is to provide a large-area transparent electroconductive film which has highly uniform properties of sheet resistance and average light transmittance on a film surface and a method of making the same.

In other words, one Embodiment according to the present invention is: (1) a large-area transparent electroconductive film characterized in that the film is a fluorine-doped tin oxide film having a film thickness of 0.3 to 1 μm, an average light transmittance is 70 to 90% in a wavelength range of 400 to 800 nm, a haze is 2 to 20% and a sheet resistance is 2 to 15Ω/□, (2) the large-area transparent electroconductive film according to (1), wherein the average light transmittance is 75 to 85% in a wavelength range of 400 to 800 nm, haze is 3 to 15% and sheet resistance is 3 to 10 Ω/□, (3) the large-area transparent electroconductive film according to (1), wherein variability of the average light transmittance is within ±3% and variability of the sheet resistance is within ±10% on a film surface, (4) the large-area transparent electroconductive film according to (1), wherein an area of the transparent electroconductive film is 100 to 10000 cm², and (5) the large-area transparent electroconductive film according to (1) used as solar light transmittance films of solar cells.

Another Embodiment according to the present invention is: (6) a method of making a large-area electroconductive film characterized in that, in a spray pyrolysis method in which a material solution is sprayed on a surface of a heated substrate placed in a horizontal direction, the material solution is sprayed on the substrate while moving a spraying nozzle in any direction on an X-Y axis.

The present invention is based on the knowledge of the inventors, while referring to a film forming method of a tin oxide (IV) film with the spray pyrolysis method as disclosed in the above-mentioned Japanese Patent No. 3655330, that a large-area transparent electroconductive film comprising an FTO film which has a much lower resistivity and which does not require a special crystal orientation can be obtained by changing a material solution temperature and film formation temperature and by introducing a mobile spraying mechanism.

### BRIEF DESCRIPTION OF DRAWINGS

FIG. 1 is an explanatory view showing an average light transmittance at each portion of a transparent electroconductive film obtained by spraying a solution with a spraying nozzle while moving the nozzle according to Example 1.

FIG. 2 is an explanatory view showing a sheet resistance at each portion of a transparent electroconductive film obtained by spraying a solution with a spraying nozzle while moving the nozzle according to Example 1.

FIG. 3 is an explanatory view showing an average light transmittance at each portion of a transparent electroconductive film obtained by fixed spraying according to Comparative Example 2.

FIG. 4 is an explanatory view showing a sheet resistance at each portion of a transparent electroconductive film obtained by fixed spraying according to Comparative Example 2.

FIG. 5 is a schematic cross-sectional view showing one Embodiment of a large-area transparent electroconductive film formed on a glass substrate according to the present invention.

FIG. 6 is a schematic explanatory view showing one Embodiment of a manufacturing apparatus used for making a large-area transparent electroconductive film according to the present invention.

### EXPLANATION OF SYMBOLS

1 glass substrate
2 large-area transparent electroconductive film
10 material solution storage tank
11 material supply pipe
12 flow meter
13 compressed gas supply section
14 gas supply pipe
15 pressure regulator
16 atomizing portion
17 biaxial driving device for atomizing portion
18 large-area transparent electroconductive film
19 substrate
20 substrate holding portion
21 heater

### BEST MODE FOR CARRYING OUT THE INVENTION

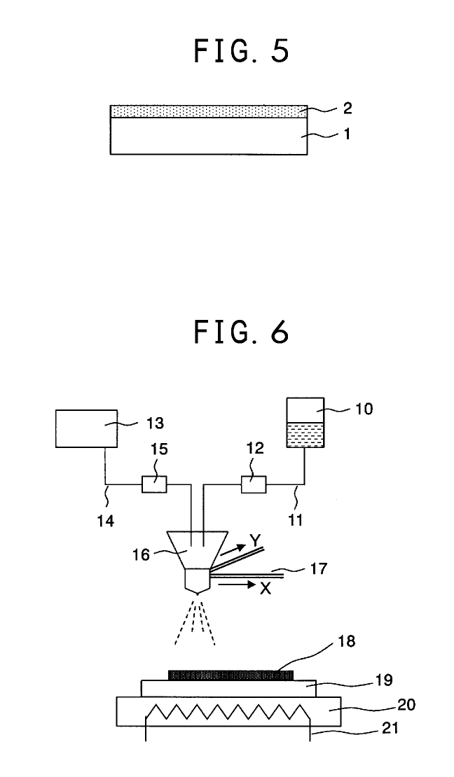

A large-area transparent electroconductive film according to the present invention is shown in FIG. 5. FIG. 5 is a schematic sectional view showing one Embodiment of a transparent electroconductive film 2 formed on a glass substrate 1.

The thickness of the large-area transparent electroconductive film according to the present invention is closely related to an average light transmittance, haze and sheet resistance of the film. When the thickness is too large, the sheet resistance is small, however, the average light transmittance decreases and haze is large. On the other hand, when the thickness is too small, the average light transmittance increases, however, the haze is small and sheet resistance is large. Therefore, in order to meet the all properties, the film thickness needs to be adjusted to be 0.3 to 1 μm, more preferably 400 to 800 nm. The average light transmittance of the large-area transparent electroconductive film according to the present invention is adjusted to be 70 to 90%, more preferably 75 to 85% so as to maintain the performance of such as solar cells, liquid crystal or plasma displays in which the film is used. If the average light transmittance is less than 70%, there is a problem that incident light is not sufficient and light conversion efficiency decreases when the film is used in solar cells. There is also a problem that a display screen darkened due to the decrease in transmission light when the film is used in liquid or plasma displays. On the other hand, there is no problem in the light transmittance if the average light transmittance is more than 90%, however, a sheet resistance of the film is large. The haze of the large-area transparent electroconductive film according to the present invention is adjusted to be 2 to 20%, and more preferably 3 to 15%. Haze represents a ratio between transmittance of diffusion light and that of direct light of the transparent conductive film and is related to the cloudiness of the film. If the haze is larger than 20%, the cloudiness of the film is large and there is a problem that displayed image becomes blur when used particularly in liquid or plasma displays. On the other hand, if the haze is smaller than 2%, there is a problem that the conversion efficiency decreases since diffusion light is not effectively used when the film is used in solar cells. A sheet resistance of a large-area transparent electroconductive film according to the present invention is adjusted to be 2 to 15Ω/□, and more preferably 3 to 10Ω/□. If the sheet resistance is larger than 15Ω/□, loss due to the increase of internal resistance is large when the film is used in solar cells, liquid or plasma displays. On the other hand, there is no problem associated with the resistivity if the sheet resistance is larger smaller than 2Ω/□, however, light transmittance becomes less than 70%.

When the size of the transparent electroconductive film is larger than 10 cm square (100 cm²), the film thickness is uneven at the center portion and edge portions of the film by the spraying method with a nozzle fixed above the center portion of a substrate. Variability of the properties such as the light transmittance and sheet resistance becomes large and thus the performance of the film largely decreases as a whole. In order to avoid this, there has been a method that a plurality of nozzles is provided above a substrate to spray the substrate from the fixed positions. However, not only that the configuration of the apparatus becomes complex due to the increased number of nozzles but the increased or decreased number of nozzles needs to be provided depending on the size of the substrate area. The inventors have developed a method for spraying a material solution on the surface of the substrate while moving one nozzle in any direction on the X-Y axis. In other words, the inventors have found that a large-area transparent electroconductive film with uniform properties can be obtained by the method of spraying while moving a spraying nozzle between any two points on the X-Y plane when the distance between the spaying nozzle and substrate is constant. The size of the large-area transparent electroconductive film is 100 to 10000 cm², more preferably 200 to 8000 cm², and most preferably 225 to 3000 cm². When the size of the film is smaller than 100 cm², there is no need to spray the solution while moving the spraying nozzle since the substrate area is small. On the other hand, when the film is larger than 10000 cm², there is a problem that the variability of the average light transmittance and sheet resistance on the film surface becomes large due to the large area of the substrate.

The large-area transparent electroconductive film according to the present invention is formed by spraying a material solution containing tin and fluorine on a heated transparent substrate made of such as glass by the spray pyrolysis method. Silica glass, soda glass or borosilicate glass may be appropriately used for the transparent substrate by considering factors such as heat resistance, light transmittance and cost. Dibutyltin diacetate, tetrabutyltin, tin tetrachloride, tin dichloride or the like may be used as a tin material and hydrofluoric acid, ammonium fluoride or the like may be used as a fluorine material. The materials are dissolved in water or alcohol such as methanol, ethanol or IPA (isopropyl alcohol) to prepare a material solution for making a film by diluting the resultant to an appropriate concentration of 0.2 to 1.0 M, for example. The material solution is sprayed on the heated transparent substrate and the large-area transparent electroconductive film according to the present invention can be obtained. The temperature for making the film is adjusted to be 400 to 600° C. at which fluorine-doped tin oxide with high crystallinity can be obtained.

When making the large-area transparent electroconductive film according to the present invention, a manufacturing apparatus for transparent electroconductive film shown in FIG. 6 may be used, for example. FIG. 6 is a schematic explanatory view showing one Embodiment of a manufacturing apparatus used for making a large-area transparent electroconductive film according to the present invention.

The material solution is stored in a material solution storage tank 10 and is introduced in an atomizing portion 16 via a material supply pipe 11. The flow rate of the material solution can be checked by a flow meter 12 provided at the material supply pipe 11. Compressed gas supplied by a compressed gas supply section 13 is used when the material solution is sprayed from the atomizing portion 16. The atomizing portion 16 is directly coupled to a biaxial driving device 17 for atomizing portion for moving the atomizing portion in any direction on the X-Y axis such that the solution can be sprayed while moving. Compressed gas is introduced in the atomizing portion 16 via the gas supply pipe 14. The pressure of the compressed gas is adjusted by a pressure regulator 15 provided at the gas supply pipe 14.

A substrate 19 is provided on a substrate holding portion 20. The material solution is sprayed from above of the substrate 19 provided on the substrate holding portion 20. When the substrate 19 is cooled by spraying the material solution, the substrate 19 can be heated to a predetermined temperature by a heater 21 mounted to the substrate holding portion 20.

In this manner, it is possible to obtain a large-area transparent electroconductive film characterized in that the film is a fluorine-doped tin oxide film having a thickness of 0.3 to 1 μm, average transmittance is 70 to 90% in a wavelength range of 400 to 800 nm, haze is 2 to 20% and sheet resistance is 2 to 15 Ω/□.

### EXAMPLES

The present invention is further described based on Examples. However, the present invention is not limited to such Examples.

### Example 1

Dibutyltin diacetate was used as a tin material and it was dissolved in ethanol to prepare a solution of 0.2 M. Aluminum fluoride was checkweighed such that an atomic ratio between tin atoms of dibutyltin diacetate and fluorine atoms of ammonium fluoride was equal and the resultant was dissolved in water of the same weight. The ammonium fluoride solution was dissolved in the ethanol solution of dibutyltin diacetate to prepare a material solution for the transparent electroconductive film.

The material solution was sprayed on a borosilicate glass substrate (available from Corning Incorporation, produce name: 1737) which had the size of 15 cm square (225 cm²) and thickness of 1.1 mm and which was heated to 550° C. by using a spray pyrolysis thin film formation apparatus (available from Global Machinery Co., Ltd., product number: KM-150). The solution was sprayed for 130 times, at a rate of 0.6 ml a time, while moving the spraying nozzle alternatively in two directions of the diagonal line of the substrate on the X-Y plane in which the distance between spaying nozzle and substrate is constant. At this time, spraying was repeated intermittently such that the glass substrate temperature did not become lower than the preset temperature (550° C.). The transparent electroconductive film of fluorine-doped tin oxide was made by cooling down naturally. The obtained transparent electroconductive film was a uniform transparent film with good adhesiveness.

### Example 2

Tin dichloride was used as a tin material and it was dissolved in ethanol to prepare a tin dichloride solution with a concentration of 0.2 M. A material solution for the transparent electroconductive film was prepared by dissolving hydrofluoric acid in the resultant such that an atomic ratio between tin atoms of tin dichloride and fluorine atoms of ammonium fluoride was equal. A soda glass substrate (available from Asahi Glass Co., Ltd.) with the size of 50 cm square (2500 cm²) and thickness of 1.5 mm was heated to 520° C. by placing it on the heater. The solution was sprayed for 11 times, at a rate of 1.5 ml a time, while moving the spraying nozzle along the longitudinal and transverse directions at an interval of 5 cm in the longitudinal and transverse directions of the substrate. The operation was repeated and the solution was sprayed for a total of 550 times. Spraying was repeated intermittently such that the glass substrate temperature did not become lower than the preset temperature and then the transparent electroconductive film of fluorine-doped tin oxide was made by cooling down naturally. The obtained transparent electroconductive film was a uniform transparent film with good adhesiveness.

### Example 3

Tin tetrachloride was diluted in water while being cooled down to prepare a tin tetrachloride stock solution of 3M and a predetermined amount of the resultant was aliquoted. A material solution for the transparent electroconductive film was prepared by dissolving aluminum fluoride in the resultant such that an atomic ratio between tin atoms of tin tetrachloride and fluorine atoms of ammonium fluoride was equal. The resultant was diluted with ethanol to obtain a material solution of 0.3 M. The material solution was sprayed on a borosilicate glass substrate (available from Corning Incorporation, produce name: 1737) which had the size of 10 cm square (100 cm²) and thickness of 1.1 mm and which was heated to 560° C. by using the spray pyrolysis thin film formation apparatus (available from Global Machinery Co., Ltd., product number: KM-150). The solution was sprayed for 100 times, at a rate of 0.5 M a time, while moving the spraying nozzle alternatively in two directions of the diagonal line of the substrate. Thereafter, the transparent electroconductive film of fluorine-doped tin oxide was made by making the film in the same manner as Example 1. The obtained transparent electroconductive film was a uniform transparent film with good adhesiveness.

### Comparative Example 1

The material solution prepared in Example 1 was sprayed on a borosilicate glass substrate (available from Corning Incorporation, produce name: 1737) which had the size of 2.5 cm square (6.25 cm²) and thickness of 1.1 mm and was heated to 520° C. The solution was sprayed for 120 times, at a rate of 0.3 ml a time, to obtain a transparent electroconductive film of fluorine-doped tin oxide. Other than that the solution was sprayed with a fixed spraying nozzle, the film was made in the same manner as Example 1. The obtained transparent electroconductive film was a uniform transparent film with good adhesiveness.

### Comparative Example 2

The material solution prepared in Example 1 was sprayed on a borosilicate glass substrate (available from Corning Incorporation, produce name: 1737) which had the size of 10 cm square (100 cm²) and thickness of 1.1 mm and was heated to 550° C. The solution was sprayed for 150 times, at a rate of 0.3 ml a time, to obtain a transparent electroconductive film of fluorine-doped tin oxide. Other than that the solution was sprayed with a fixed spraying nozzle, the film was made in the same manner as Example 1. The obtained transparent electroconductive film had uneven film thickness between the center portion and edge portions of the substrate.

### Comparative Example 3

The material solution prepared in Example 1 was sprayed on a borosilicate glass substrate (available from Corning Incorporation, produce name: 1737) which had the size of 15 cm square (225 cm²) and thickness of 1.1 mm and was heated to 550° C. The solution was sprayed for 30 times, at a rate of 0.6 ml a time, while moving the spraying nozzle alternatively in two directions of the diagonal line of the substrate to obtain a transparent electroconductive film of fluorine-doped tin oxide. Other than those conditions, the film was made in the same manner as Example 1. The obtained transparent electroconductive film was a uniform transparent film with good adhesiveness.

### Comparative Example 4

The material solution prepared in Example 1 was sprayed on a borosilicate glass substrate (available from Corning Incorporation, produce name: 1737) which had the size of 15 cm square (225 cm²) and thickness of 1.1 mm and was heated to 550° C. The solution was sprayed for 300 times, at a rate of 0.6 ml a time, while moving the spraying nozzle alternatively in two directions of the diagonal line of the substrate to obtain a transparent electroconductive film of fluorine-doped tin oxide. Other than those conditions, the film was made in the same manner as Example 1. The obtained transparent electroconductive film was a uniform transparent film with good adhesiveness.

The material properties of the transparent electroconductive films obtained in accordance with respective Examples and Comparative Examples were evaluated based on the following methods.

[Average Light Transmittance in a Wavelength Range of 400 to 800 nm].

The transmittance of diffusion light in a wavelength range of 400 to 800 nm of the transparent electroconductive films was measured by a spectrophotometer (available from JASCO Corporation, product No. V-570). The integral area of light transmittance in the measured wavelength range was then divided by the wavelength interval to calculate the average light transmittance (Td) in a wavelength range of 400 to 800 nm.

[Haze]

In the same manner as the measurement method of the average light transmittance, the transmittance of direct light was measured in a wavelength range of 400 to 800 nm to calculate the average transmittance (Tn). A haze (HR) was obtained from the average transmittance of diffusion light (Td) and the average transmittance of direct light (Tn) by using the following equation;

HR(%)=(Td−Tn)/(Td×100)

[Sheet Resistance]

The sheet resistance of the transparent electroconductive films was measured by using four-terminal sheet resistivity meter (available from Mitsubishi Chemical Corporation, product name: Loresta-GPMCP-T600).

[Crystal Orientation]

The orientation of the transparent electroconductive films was examined to obtain plane indices of the strongest peak in the X-ray diffraction patterns by taking a measurement under the condition of 30 kV-20 mA using a Cu—Kα ray within a range in which 2θ is 20 to 60 deg by using an X-ray diffraction device (available from Rigaku Industrial Corp., product number: RINT-2000).

[Film Thickness]

Film thickness was obtained by studying the cross section of the transparent electroconductive film with an electron microscope (available from JOEL Ltd., product number: JSM-6320).

[Property Variability]

Transparent electroconductive film samples with the substrate sizes of 10 cm square (100 cm²), 15 cm square (225 cm²) and 50 cm square (2500 cm²) were cut into the samples of 25 pieces with 2 cm square each, 25 pieces with 3 cm square each and 100 pieces with 5 cm square each, respectively. The average light transmittance and sheet resistance at respective portions were measured and mean values, maximum values and minimum values were obtained to examine variability. The film thickness was evaluated by taking out one central portion and four edge portions from the samples of the respective substrate sizes. The crystal orientation of the films was evaluated by taking out one sample from the central portion.

The mean values of the film thickness, average light transmittance, sheet resistance and haze as well as the strongest peak of X-ray diffraction patterns of respective transparent electroconductive films obtained in respective Examples and Comparative Examples are shown in Table 1.

TABLE 1

| | Substrate | Film | | | Sheet | Strongest |
|---|---|---|---|---|---|---|
| | Area | Thickness | Average Light | | Resistance | Peak Plane |
| | (cm²) | (nm) | Transmittance (%) | Haze (%) | (Ω/□) | Index |
| Ex. 1 | 225 | 610 | 81 | 3.1 | 6.7 | 200 |
| Ex. 2 | 2500 | 770 | 78 | 6.2 | 8.3 | 211 |
| Ex. 3 | 100 | 580 | 82 | 3.8 | 5.9 | 211 |
| Com. Ex. 1 | 6.25 | 640 | 81 | 3.8 | 7.2 | 200 |
| Com. Ex. 2 | 100 | 380 | 78 | 33.7 | 147 | 200 |
| Com. Ex. 3 | 225 | 120 | 89 | 1.5 | 93 | 200 |
| Com. Ex. 4 | 225 | 1330 | 67 | 57.2 | 3.5 | 200 |

In Table 2, the mean values, maximum values and minimum values of the average light transmittance and sheet resistance are shown. In Table 2, the ratios of the difference between the maximum values and minimum values relative to the mean values of the average light transmittance and sheet resistance are also shown as variability (%).

TABLE 2

| | Substrate | Average Light | | | | Sheet Resistance | | | |
|---|---|---|---|---|---|---|---|---|---|
| | Area | Transmittance (%) | | | Variability | (Ω/□) | | | Variability |
| | (cm²) | Mean | Max | Min | (%) | Mean | Max | Min | (%) |
| Ex. 1 | 225 | 81 | 81 | 80 | 1.2 | 6.4 | 6.9 | 5.8 | 17 |
| Ex. 2 | 2500 | 78 | 80 | 76 | 5.1 | 8.3 | 9.1 | 7.6 | 18 |
| Ex. 3 | 100 | 82 | 82 | 81 | 1.2 | 5.9 | 6.3 | 5.4 | 15 |
| Com. Ex. 1 | 6.25 | 81 | 81 | 80 | 1.2 | 7.2 | 7.6 | 6.6 | 14 |
| Com. Ex. 2 | 100 | 78 | 90 | 43 | 60 | 147 | 240 | 4 | 161 |
| Com. Ex. 3 | 225 | 89 | 90 | 88 | 2.2 | 93 | 101 | 85 | 17 |
| Com. Ex. 4 | 225 | 67 | 68 | 65 | 4.5 | 3.5 | 3.8 | 3.2 | 17 |

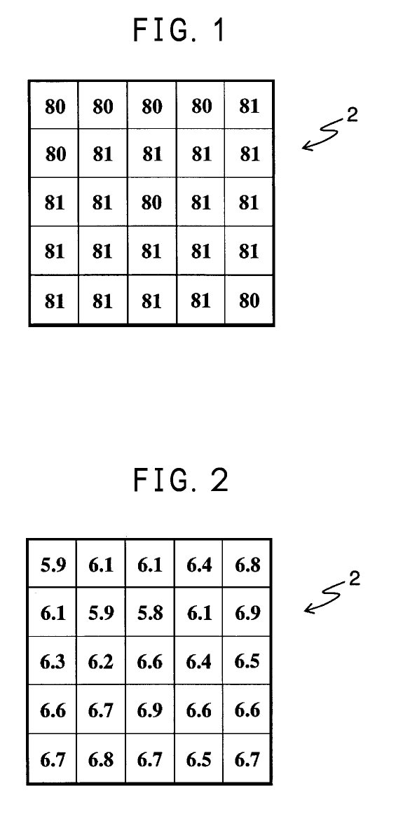

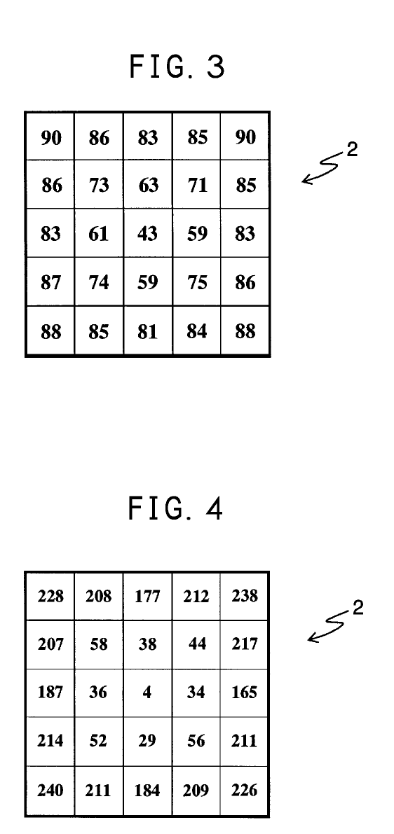

FIGS. 1 and 2 show the measurement results of the average light transmittance (%) and sheet resistance (Ω/□) at respective portions of the sample (transparent electroconductive film 2) obtained in Example 1. FIGS. 3 and 4 show the measurement results of the average light transmittance (%) and sheet resistance (Ω/□) at respective portions of the sample (transparent electroconductive film 2) obtained in Comparative Example 2.

From the results shown in Table 1, it is understood that the transparent electroconductive films obtained in respective Examples are high-performance large-area electroconductive films with the average light transmittance of 75 to 85%, haze of 3 to 15% and sheet resistance of 3 to 10Ω/□. Furthermore, it is understood from Table 2 that any of the transparent electroconductive films obtained in respective Examples are large-area electroconductive films in which the variability of the average transmittance is within ±3% and the variability of the sheet resistance is within ±10% and thus the quality thereof is uniform over the whole film surface.

The film obtained according to Comparative Example 1 was obtained by spraying the solution on the substrate with a small area (6.25 cm²) by a fixed spraying nozzle and there is no problem regarding its properties and variability. However, it is understood that the film obtained according to Comparative Example 2 where the substrate was enlarged (100 cm²) with the remaining condition the same has large variability of the average light transmittance and sheet resistance on the film surface. Furthermore, it is understood from Comparative Examples 3 and 4 that even when the transparent electroconducting film is obtained by spraying the solution while moving the spraying nozzle, the film thickness needs to be suitably adjusted since the sheet resistance is large when the film thickness is small and light transmittance is small when the thickness is large. The strongest peak planes of the transparent electroconductive films according to Examples 1 to 3 are (200), (211) and (211) planes, respectively and thus all of the films have substantially uniform and excellent properties as transparent electroconductive films. Therefore, it is understood that there is no need of a crystal orientation on a specific peak plane in order to obtain the above-mentioned material properties.

FIGS. 1 and 2 show the average light transmittance and sheet resistance at respective portions of the transparent electroconductive film according to Example 1 in which the solution was sprayed by moving the spraying nozzle. It is understood that the variability is within ±3% for the average light transmittance and ±10% for the sheet resistance on the film surface and thus the property distribution is uniform. On the other hand, FIGS. 3 and 4 show the average light transmittance and sheet resistance at respective portions of the transparent electroconductive film according to Comparative Example 2 in which the solution was sprayed by the fixed spraying nozzle. It is understood that the variability of the average light transmittance and sheet resistance at the central portion and edge portions of the film is large.

### INDUSTRIAL APPLICABILITY

The large-area transparent electroconductive film according to the present invention has a high light transmittance and low sheet resistance and the variability thereof on the film surface is small. Therefore, the film with a high haze can be preferably used in transparent electrodes for windows of solar cells (particularly dye sensitive solar cells) and transparent electrodes for displays used in such as liquid crystal displays and plasma displays.

The large-area transparent electroconductive film according to the present invention is a transparent electroconductive film characterized in that the film is a fluorine-doped tin oxide film having a thickness of 0.3 to 1 μm, average transmittance is 70 to 90% in a wavelength range of 400 to 800 nm, haze is 2 to 20% and the sheet resistance is 2 to 15Ω/□. Therefore, the film can be preferably used in transparent electrodes for windows used in solar cells (particularly dye sensitive solar cells), transparent electrode used in such as crystal liquid displays and plasma displays for televisions and transparent electrode for display elements used in such as laptop computers and cell phones, for example.

1. A large-area transparent electroconductive film characterized in that the film is a fluorine-doped tin oxide film having a film thickness of 0.3 to 1 μm, an average light transmittance is 70 to 90% in a wavelength range of 400 to 800 nm, a haze is 2 to 20% and a sheet resistance is 2 to 15 Ω/□.

2. The large-area transparent electroconductive film according to claim 1, wherein the average light transmittance is 75 to 85% in a wavelength range of 400 to 800 nm, haze is 3 to 15% and sheet resistance is 3 to 10 Ω/□.

3. The large-area transparent electroconductive film according to claim 1, wherein variability of the average light transmittance is within ±3% and variability of the sheet resistance is within ±10% on a film surface.

4. The large-area transparent electroconductive film according to claim 1, wherein an area of the transparent electroconductive film is 100 to 10000 cm².

5. The large-area transparent electroconductive film according to claim 1 used as a solar light transmittance film of a solar cell.

6. A method of making a large-area electroconductive film characterized in that, in a spray pyrolysis method in which a material solution is sprayed on a surface of a heated substrate placed in a horizontal direction, the material solution is sprayed on the substrate while moving a spraying nozzle in any direction on an X-Y axis.
